(19) United States
(12) Patent Application Publication
(10) Pub. No.: US 2017/0352802 A1
(43) Pub. Date: Dec. 7, 2017

(54) MAGNETO-ELECTRIC DEVICES AND INTERCONNECT

(71) Applicant: Intel Corporation, Santa Clara, CA (US)

(72) Inventors: Dmitri Nikonov, Beaverton, OR (US); Sasikanth Manipatruni, Hillsboro, OR (US); Ian Young, Portland, OR (US)

(73) Assignee: Intel Corporation, Santa Clara, CA (US)

(21) Appl. No.: 15/525,521

(22) PCT Filed: Dec. 18, 2014
(86) PCT No.: PCT/US2014/071215

§ 371 Date: May 9, 2017

(51) Int. Cl. H01L 43/08; G11C 11/16; H01L 43/10; H01L 41/12

(52) U.S. Cl. CPC H01L 43/08; H01L 43/10; G11C 11/161; G11C 11/1675; H01L 41/12

(57) ABSTRACT

Described is an interconnect which comprises: a first end having a ferromagnetic layer coupled to a first magnetoelectric material layer; and a second end having a second magnetoelectric material layer coupled to the ferromagnetic layer, wherein the ferromagnetic layer extends from the first end to the second end. Described is a majority gate device which comprises: a ferromagnetic layer; and first, second, third, and fourth magnetoelectric material layers coupled to the ferromagnetic layer. Described is an apparatus which comprises: a first end having a ferromagnetic layer coupled to a first magnetoelectric material layer; and a second end having a tunnel junction device coupled to the ferromagnetic layer. Described is an apparatus which comprises: a first terminal coupled to a tunneling junction device; a second terminal coupled to a layer coupling the tunneling junction device and a magnetoelectric device; and a third terminal coupled to the magnetoelectric device.

### BACKGROUND

On chip devices with non-volatility can enable energy and computational efficiency. An example of a non-volatile device is a Spin-Transfer Torque Magnetic Random Access Memory (STT-MRAM). However, STT-MRAM suffers from high voltage and high current-density problems during the programming (i.e., writing) of a bit-cell. The process of switching magnetization directions in the ferromagnets of STT-MRAM may be a slow process.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-section of a device having multiferroic material that is operable to generate a magnetoelectric (ME) field by exchange bias at an interface of a ferromagnetic (FM) material and a ME material, according to some embodiments.

FIG. 2 illustrates a cross-section of a three terminal (3T) memory cell formed by a combination of tunneling junction device and an ME device, according to some embodiments of the disclosure.

FIG. 3 illustrates a cross-section of a 2T memory cell formed by a ME device, according to some embodiments of the disclosure.

FIG. 4 illustrates cross-section of an interconnect having an ME device on one end and a tunnel junction device at another end, according to some embodiments of the disclosure.

FIG. 5A-B illustrate cross-sections of interconnects having magnetoelectric devices at either ends of interconnects, according to some embodiments of the disclosure.

FIG. 6 illustrates a three dimensional (3D) view of an interconnect having ME devices at either ends of the interconnect, according to some embodiments of the disclosure.

FIG. 7A illustrates a cross-section of a majority gate formed using ME devices, according to some embodiments of the disclosure.

FIG. 7B illustrates a top-view of the majority gate of FIG. 7A, according to some embodiments of the disclosure.

FIG. 8 illustrates a 3D view of a majority gate having a ring structure, according to some embodiments of the disclosure.

FIG. 9 illustrates a hybrid interconnect having two interconnects with ME devices such that the two interconnects are coupled by a non-magnetic conductor, according to some embodiments of the disclosure.

FIG. 10 illustrates a hybrid interconnect having two interconnects with ME devices such that the two interconnects are coupled by a non-magnetic conductor and transistor, according to some embodiments of the disclosure.

FIG. 11 illustrates a flowchart of a method for forming and using an interconnect having ME devices, according to some embodiments of the disclosure.

FIG. 12 illustrates a smart device or a computer system or a SoC (System-on-Chip) with an interconnect having ME devices, a memory cell, and/or a majority gate, according to some embodiments.

### DETAILED DESCRIPTION

Some embodiments describe a magnetoelectric (ME) device which exhibits faster switching speeds at much lower energy expense compared to switching of magnetization using spin transfer torque (STT). An ME device uses magnetoelectric effect for fast switching, where the ME effect is induction of magnetization by an electric field or of polarization by a magnetic field.

In some embodiments, a magnetic element is switched by a multiferroic material. Some embodiments describe a memory device using ME devices that exhibit non-volatility and fast read and write operations. In some embodiments, an ME device is coupled to a Magnetic Tunnel Junction (MTJ) device to form a memory cell.

Some embodiments describe an interconnect having a ferromagnetic (FM) material based wire and ME devices at the ends of the FM wire. As input voltage is applied at one of the ME devices on one end, a domain wall (DW) is formed which starts to propagate along the FM wire to the other ME device on the other end of interconnect (or the FM wire). In some embodiments, magnetization under the ME device that behaves as an output ME cell affects the antiferromagnetic order in the output ME cell and thus induces voltage (i.e., output voltage) corresponding to the applied input voltage.

In some embodiments, FM/ME interconnects are cascaded or coupled to each other using a non-magnetic wire (e.g., Cu wire) coupling an ME device at one end of the FM interconnect of a first FM/ME interconnect to the ME device at one end of another FM interconnect of a second FM/ME interconnect. In some embodiments, transistors are coupled between the first and second FM/ME interconnects. Some embodiments describe a majority gate device using ME devices for performing logic operation on multiple signals.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” may means a direct electrical connection between the things that are connected, without any intermediary devices. The term “connected” may also means a magnetic connection. For example, connection via domain wall (DW) propagation in a ferromagnetic wire or magnetic state in the ferromagnetic wire. The term “coupled” means either a direct electrical connection between the things that are connected or an indirect connection through one or more passive or active intermediary devices. The term “coupled” may also means magnetic coupling. For example, coupling via DW propagation in a ferromagnetic wire or magnetic state in the ferromagnetic wire. The term “circuit” means one or more passive and/or active components that are arranged to cooperate with one another to provide a desired function. The term “signal” means at least one current signal, voltage signal, data/clock signal, magnetic DW, or electromagnetic signal, etc. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter. For example, by reducing power supply level of a circuit generating an oscillating signal, the frequency of that oscillating signal can be scaled down. The terms “substantially,” “close,” “approximately,” “near,” and “about,” generally refer to being within +/−20% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors in various circuits and logic blocks are metal oxide semiconductor (MOS) transistors, which include drain, source, gate, and bulk terminals. The transistors also include Tri-Gate and FinFET transistors, Gate All Around Cylindrical Transistors, Tunneling FET (TFET), Square Wire, or Rectangular Ribbon Transistors or other devices implementing transistor functionality like carbon nanotubes or spintronic devices. MOSFET symmetrical source and drain terminals, i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.).

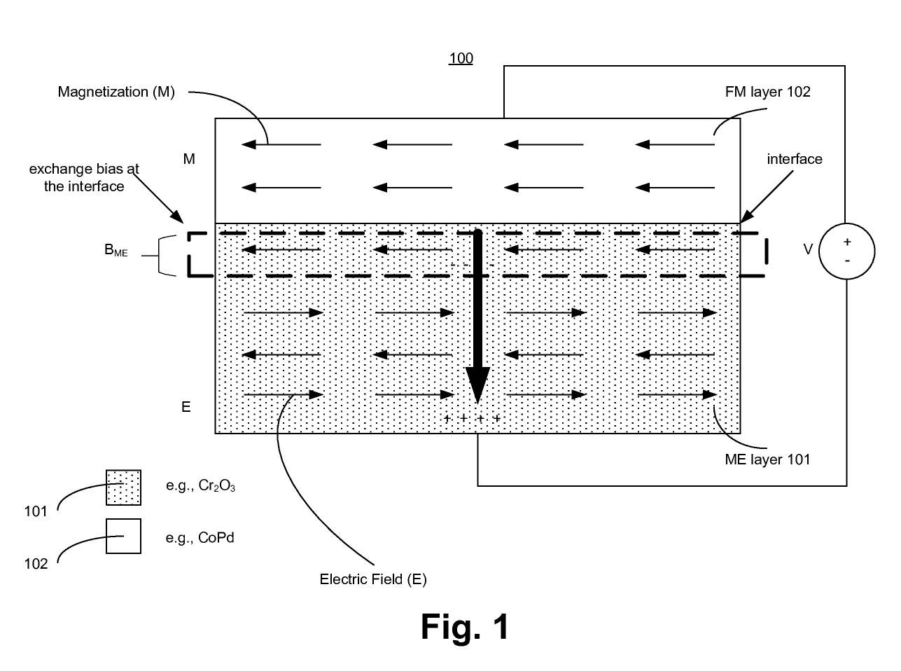

FIG. 1 illustrates a cross-section 100 of a device having multiferroic material that is operable to generate a ME field by exchange bias at an interface of the a FM material and a ME material, according to some embodiments. Multiferroic materials may have both spontaneous (i.e., remnant) electric and magnetic polarizations. In some cases a single ME layer can be used instead of a multiferroic layer, where the single ME layer contains both electric and magnetic polarization in itself. The device here is a composite multiferroic ME device. The term “composite multiferroic” (also referred to as synthetic, hybrid, or multilayer magnetoelectric or multiferroic) generally refers to the ME and FM layers together.

Cross-section 100 illustrates ME layer 101 coupled to FM layer 102 such that when a voltage (V) is applied across the two layers as shown, an effective magnetoelectric field (B_{ME}) is formed by exchange bias at the interface of ME layer 101 and FM layer 102, according to some embodiments. In this case, ME layer 101 exerts exchange bias on FM layer 102. ME layer 101 has an electric polarization or strain as shown by the Electric Field (E) while FM layer 102 has magnetization as shown by Magnetization (M). The field interaction at the interface (i.e., B_{ME}) produces the switching of the device. Here, precessional (rather than relaxational) switching is exhibited by the ME field perpendicular to the magnetization (M) by virtue of the strength of the B_{ME}.

ME layer 101 that exerts exchange bias to form an effective magnetization B_{ME} can be formed of BiFeO₂, Cr₂O₃, etc., according to some embodiments. FM layer 102 can be formed of various materials, according to some embodiments. For example, to generate an in-plane magnetization, FM layer 102 can be formed using one of: CoFe, CoFeB, Co, Ni, NiFe (permalloy), Terfenol-D (e.g., TbxDyl-xFe2), etc. To generate an out-of plane magnetization, FM layer 102 can be formed using one of: CoPd, CoPt, CoNi multilayers, Heusler Alloys (e.g., Co₂FeAl, Mn₂Ge, Mn₂Ga). The device of FIG. 1 provides the basis for efficient switching, according to some embodiments.

While various embodiments are described with reference to the ME layer exerting exchange bias on a FM layer, the ME layer can be a piezoelectric layer that exerts strain on the FM layer and uses magnetostrictive effect, according to some embodiments. In some embodiments, the ME layer is a plain dielectric such that when a voltage is applied across it, surface anisotropy of the FM layer changes. In some embodiments, more layers may be added in addition to ME layer 101 and FM layer 102.

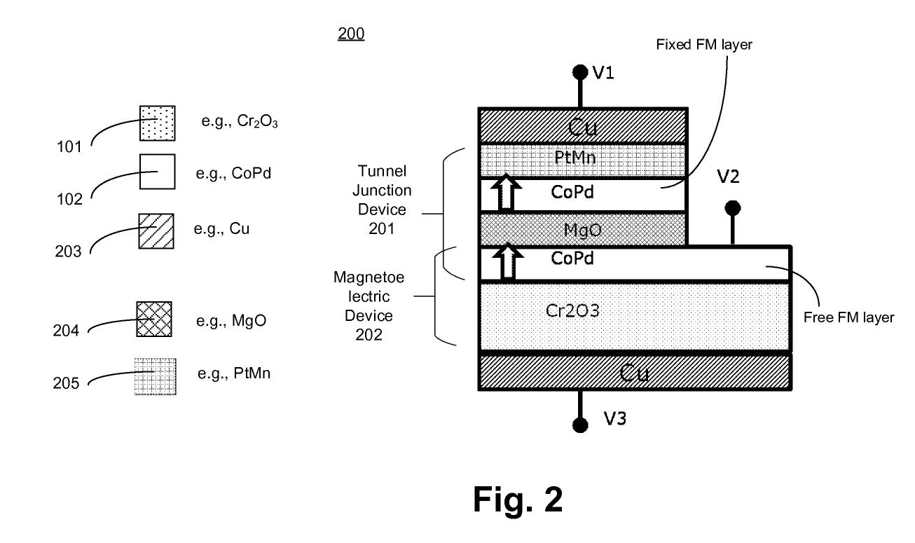

FIG. 2 illustrates a cross-section of a three terminal (3T) memory cell 200 formed by a combination of tunneling junction device and ME device, according to some embodiments of the disclosure. It is pointed out that those elements of FIG. 2 having the same reference numbers (or names) as the elements of any other figure can operate or function in any manner similar to that described, but are not limited to such.

On chip embedded memory with non-volatility can enable energy and computational efficiency. However, leading embedded memory options such as Spin-Transfer Torque Magnetic Random Access Memory (STT-MRAM) suffer from high voltage and high current-density problems during the programming (i.e., writing) of a bit-cell. For example, large write current (e.g., greater than 100 μA) and voltage (e.g., greater than 0.7V) may be required for tunnel junction based Magnetic Tunnel Junction (MTJ) to perform a write operation in a MTJ based STT-MRAM bit-cell. This large write current and voltage is needed because write operation may require writing through tunnel oxides. However, large write currents may cause reliability issues to the devices. To address this problem (and others), in some embodiments, ME and MTJ devices are combined to form a memory cell such that the memory cell is written by a ME effect faster and with lesser energy with no current passing through the MTJ. The combined cell is then read with a small current through the MTJ, in which the tunnel oxide can be made thicker (i.e., more resistive) and can have a higher tunneling magnetoresistance (TMR) ratio.

In some embodiments, memory cell 200 comprises MTJ device 201 coupled to ME device 202. In some embodiments, memory cell 200 has three terminals, V1-V3. In some embodiments, terminal V1 is coupled to a non-magnetic metal layer (e.g., Cu) coupled to MTJ device 201. In some embodiments, terminal V2 is coupled to FM layer 102 (e.g., CoPd) which also behaves as a free magnetic layer of MTJ device 201 as well as the FM layer for ME device 202. For example, the FM layer under the PtMn layer is the fixed FM layer in the MTJ device. In some embodiments, terminal V2 is coupled to a non-magnetic metal layer 203 (e.g., Cu) coupled to ME layer 101 (e.g., Cr₂O₃).

In some embodiments, MTJ device 201 comprises layers including: anti-ferromagnetic layer; fixed magnetic layer; exchange coupling layer; fixed magnetic layer; tunnel oxide (e.g., MgO 204); and free magnetic layer 102. In some embodiments, free magnetic layer 102 has magnetostriction. In some embodiments, MTJ device 201 includes an anti-ferromagnetic layer 205 (e.g., IrMn, PtMn, etc.) formed below the non-magnetic metal layer 203 coupled to terminal V1. Anti-ferromagnetic material can be used for pinning FM layer (i.e., the fixed ferromagnetic layer).

In some embodiments, data is written to memory cell 200 by providing a potential difference between terminals V2 and V3. This potential difference switches magnetization (e.g., using exchange bias as described with reference to FIG. 1). Referring back to FIG. 2, in some embodiments, data is read from memory cell 200 by sensing a potential difference between terminals V1 and V2, and sensing the value of current between V1 and V2, for example using a sense amplifier. The value of current and of the associated resistance between terminals V1 and V2 depends on the relative directions of magnetization of layers 102a and 102b due to the TMR effect. Typically the state with parallel magnetization has a lower resistance than the state with anti-parallel magnetizations. The ratio of the two resistances (i.e., the TMR ratio) is typically between 1.5 and 4. The layer 102b has magnetization direction which is fixed in most of the situations due to the strong interaction with the antiferromagnetic layer 205. Therefore, as the magnetization of layer 102a is switched, so is the value of resistance.

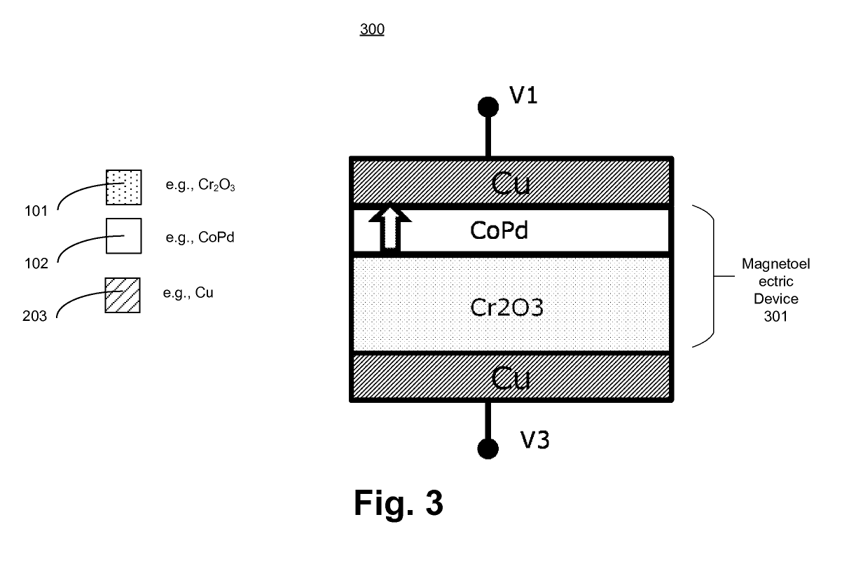

FIG. 3 illustrates a cross-section of a two terminal (2T) memory cell 300 formed by a ME device, according to some embodiments of the disclosure. It is pointed out that those elements of FIG. 3 having the same reference numbers (or names) as the elements of any other figure can operate or function in any manner similar to that described, but are not limited to such.

Memory cell 300 is similar to device described with reference to FIG. 1 except that the non-magnetic layers are formed on top of FM layer 102 and ME layer 201. Non-magnetic layers can be formed of Cu. FM layer 102 can be formed of CoPd. ME layer 201 can be formed of Cr₂O₃. In other embodiments, other types of materials may be used for forming the non-magnetic layers, FM layer 102, and ME layer 201. In some embodiments, one of the non-magnetic layer forms the first terminal V1 and the other non-magnetic layer forms the second terminal V3 (keeping the same terminal naming convention as that described with reference to FIG. 2), where ME device 301 is sandwiched between the terminals V1 and V3. In some embodiments, when a potential difference is applied across the terminals V1 and V3 over a certain period of time (e.g., a voltage pulse), magnetization is switched (i.e., data is written to memory cell 300). In some embodiments, to read data from memory cell 300, a change in the dc voltage difference between V1 and V3 is sensed (e.g., by a sense amplifier).

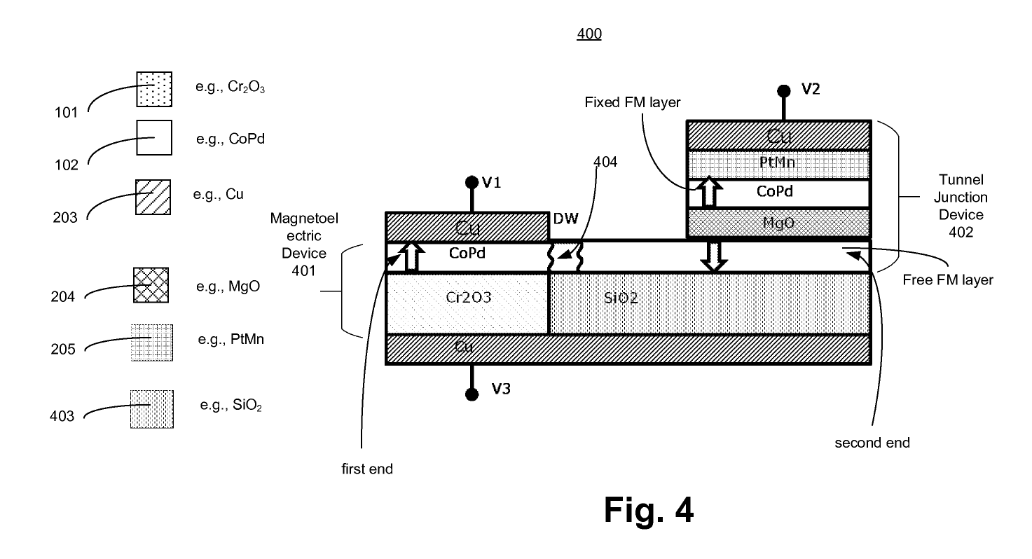

FIG. 4 illustrates a cross-section 400 of an interconnect having a ME device on one end and a tunnel junction device at another end, according to some embodiments of the disclosure. It is pointed out that those elements of FIG. 4 having the same reference numbers (or names) as the elements of any other figure can operate or function in any manner similar to that described, but are not limited to such.

In some embodiments, the interconnect comprises FM layer 102 stretched between two ends—the first end and the second end. In some embodiments, the first end has ME layer 101 coupled to FM layer 102 forming ME device 401. In some embodiments, the second end forms MTJ device 402 such that FM layer 102 behaves as the free magnetic layer for MTJ device 402. In some embodiments, the region below FM layer 102, and adjacent to ME layer 102, is formed of SiO₂ 403.

In some embodiments, the first terminal V1 is coupled to a non-magnetic layer (e.g., Cu) formed above FM layer 102 at the first end. In some embodiments, the second terminal V2 is coupled to a non-magnetic layer (e.g., Cu) which is coupled to the anti-ferromagnetic layer 205 (e.g., PtMn). In some embodiments, the third terminal V3 is coupled to a non-magnetic layer (e.g., Cu) which extends from the first end to the second end. In some embodiments, when a voltage is applied to the terminal V1, an effective magnetoelectric field (B_{ME}) is formed by an exchange bias at the interface of ME layer 101 and FM layer 102.

In some embodiments, B_{ME}, forms DW 404 which starts to propagate along FM layer 102 to the second end of the interconnect. In some embodiments, when DW 404 reaches the second end, it changes the magnetization of FM layer 102 for the “free magnet” layer of MTJ 402. The magnetization direction of FM layer 102, under dielectric 204, determines the resistance of MJT 402. For example, if the magnetization direction of FM layer 102b, under dielectric 204, parallel to the magnetization direction of the fixed magnetic layer, then MTJ 402 shows low resistance, and if the magnetization directions are anti-parallel, it shows high resistance across terminals V2 and V3 (i.e., the TMR effect).

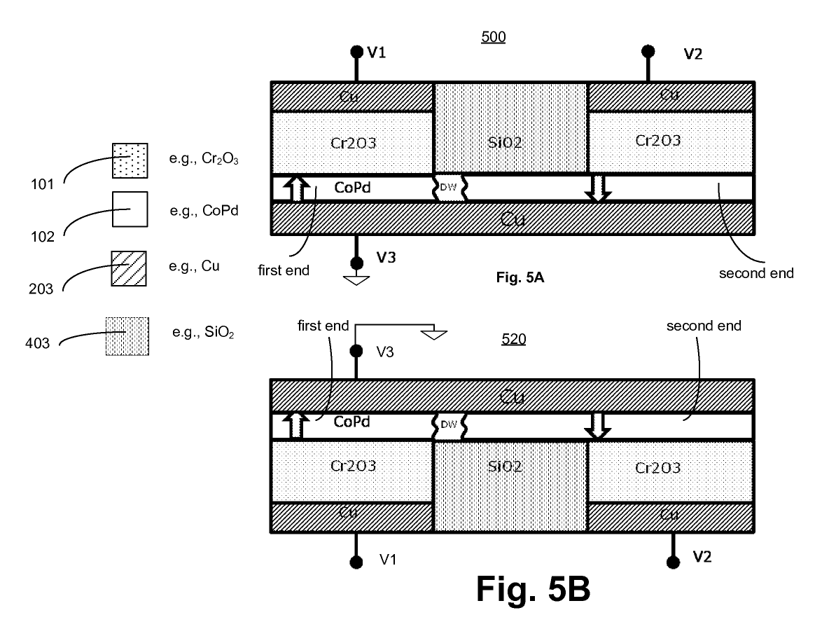

FIGS. 5A-B illustrate cross-sections 500 and 520 of interconnects having ME devices at either ends of interconnects, according to some embodiments of the disclosure. It is pointed out that those elements of FIGS. 5A-B having the same reference numbers (or names) as the elements of any other figure can operate or function in any manner similar to that described, but are not limited to such. So as not to obscure the various embodiments, FIGS. 5A-B are described with reference to FIG. 4.

Compared to cross-section 400 of FIG. 4, cross-sections 500 and 520 show ME devices formed at either ends of the FM interconnect. In some embodiments, when a voltage is applied to the first terminal V1 (which is at the first end of the FM interconnect) an effective magnetoelectric field (B_{ME}) is formed by an exchange bias at the interface of ME layer 101 and FM layer 102. This B_{ME}, creates a DW (i.e., the magnetization in the FM switches and a DW is created). The DW propagates from the first end of the FM interconnect to the second end of the FM interconnect. In some embodiments, the ME device on the second end behaves as an output ME cell, where terminal V2 is the output terminal. The magnetization that “propagates” as a DW from the first end to the second end affects the antiferromagnetic order in the output ME cell and thus induces voltage (i.e., output voltage) on the terminal V2 corresponding to the applied input voltage on terminal V1.

In cases where B_{ME}, is parallel to the magnetization, switching is relaxation (i.e., magnetization tends to the state of lower energy gradually with time as the effective field B_{ME}, remains on). If switching is precessional, the effective field B_{ME}, makes the magnetization rotate by an angle proportional to a short duration of its application. In some embodiments, when switching is precessional, precise timing of the field duration may be required. Interconnects of various embodiments are unlike traditional interconnects in that these interconnects of various embodiments are non-volatile. For example, when all voltages on terminals V1, V2, and V3 are turned off, the state of magnetization in FM layer 102 is preserved and so the data on the interconnect is not lost.

Cross-section 520 of FIG. 5B is similar to cross-section 500 of FIG. 5A except that the process of forming the interconnect is flipped. For example, instead of forming a layer of non-magnetic conductive layer (e.g., Cu) first, and then forming FM layer 102 to couple to it, that step is performed later. Operation wise, the interconnect shown by cross-section 520 behaves the same as the interconnect shown by cross-section 500.

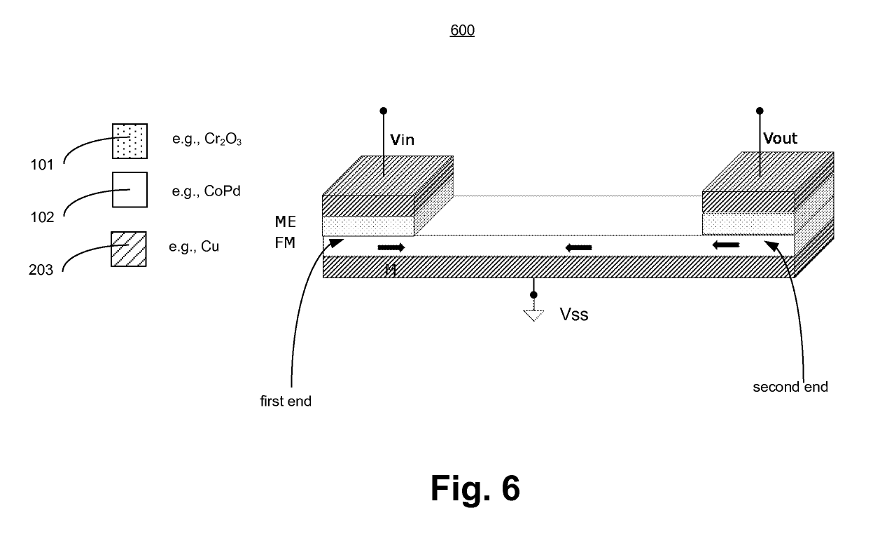

FIG. 6 illustrates a three dimensional (3D) view 600 of an interconnect having ME devices at either ends of interconnects, according to some embodiments of the disclosure. It is pointed out that those elements of FIG. 6 having the same reference numbers (or names) as the elements of any other figure can operate or function in any manner similar to that described, but are not limited to such. FIG. 6 is a 3D view of cross-section FIG. 5A. For sake of simplicity, SiO₂ 403 is not shown. Here, terminal Vin is the same as terminal V1, terminal Vout is the same as terminal V2, and terminals V3 is grounded. Interconnect of FIG. 6 operates the same way as interconnect described with reference to FIG. 5A.

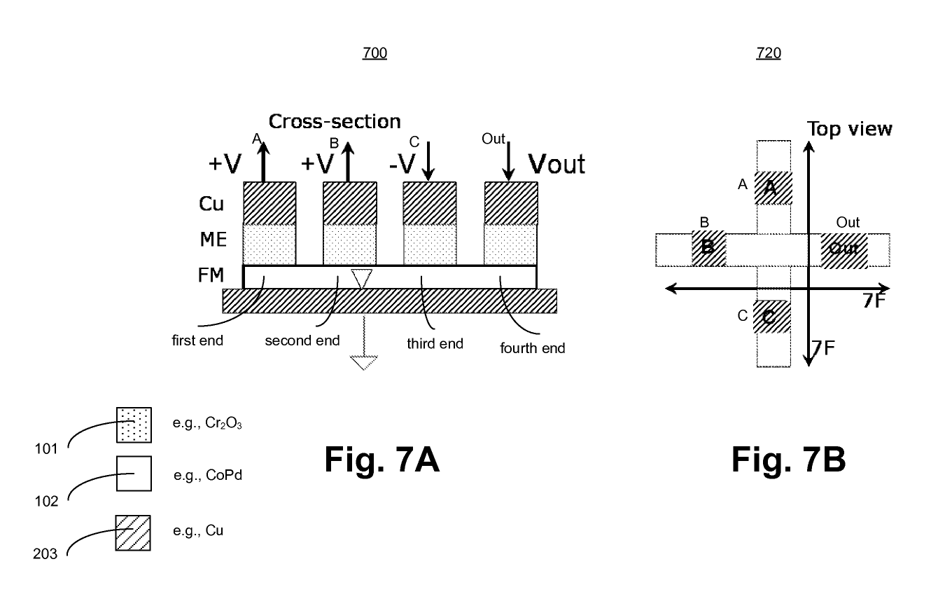

FIG. 7A illustrates cross-section 700 of a majority gate formed using ME devices, according to some embodiments of the disclosure. It is pointed out that those elements of FIG. 7A having the same reference numbers (or names) as the elements of any other figure can operate or function in any manner similar to that described, but are not limited to such.

In some embodiments, logic operations are performed using majority gates. In some embodiments, majority gate is a three input majority gate having input terminals A, B, and C, and one output terminal Out. In this example, a positive voltage pulse+V is applied to terminal A, a positive voltage pulse+Vis applied to terminal B, and a negative voltage pulse−V is applied to terminal C.

The application of the voltages at terminals A, B, and C cause multiple DWs to propagate on FM layer 102 due to exertion of exchange bias at the interface of respective ME layers 101 and FM layer 102 (i.e., DWs are formed at first, second, and third ends according to the applied voltages). Depending on the orientation of the magnetization after the DWs (which depends on the applied voltage), magnetization that “propagates” from the regions of FM layer 102 under the respective ME layers 101 to the end terminal (i.e., the Out terminal Vout) affects the antiferromagnetic order in the output ME cell and thus induces voltage Vout on terminal Out.

FIG. 7B illustrates a top-view 720 of the majority gate of FIG. 7A, according to some embodiments of the disclosure. It is pointed out that those elements of FIG. 7B having the same reference numbers (or names) as the elements of any other figure can operate or function in any manner similar to that described, but are not limited to such. Here, 7F×7F are the width by height layout dimensions, where ‘F’ is the metal one half pitch, and ‘F’ is 2*λ, for lambda (λ) based design rules.

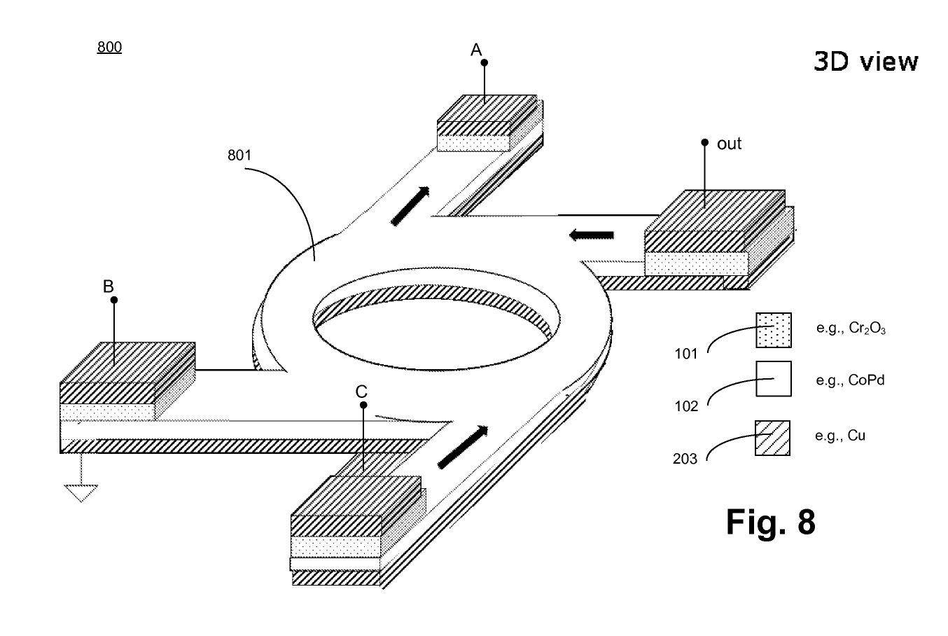

FIG. 8 illustrates 3D view 800 of a majority gate having a ring structure, according to some embodiments of the disclosure. It is pointed out that those elements of FIG. 8 having the same reference numbers (or names) as the elements of any other figure can operate or function in any manner similar to that described, but are not limited to such.

In some embodiments, the addition of the states on in-plane magnetization is performed in a round-about ring structure. Like the embodiment of FIG. 7A, here, there are three input terminals A, B, and C, and one output Out terminal. Referring back to FIG. 8, depending on the magnitude and sign of the voltages applied on terminals A, B, and C, magnetization and DWs propagate (as shown by the arrows) on FM layer 101 and set the magnetization on the ring of FM layer 101 to be in the clockwise or counter-clockwise directions. The output ME cell (having terminal Out) induces a voltage determined by the direction of magnetization under it, according to some embodiments. Compared to spin torque transfer in which magnetization switching is current driven, ME devices are voltage driven and so consume lower energy than STT devices. As such, in some embodiments, ME devices do not need thick tunneling layers, fixed/free magnets as used in MTJ devices.

In some embodiments, depending on the magnitude and sign of the voltages applied on terminals A, B, and C, different majority and Boolean logic functions (AND/NAND, OR/NOR) can be performed by the majority gate of FIG. 8.

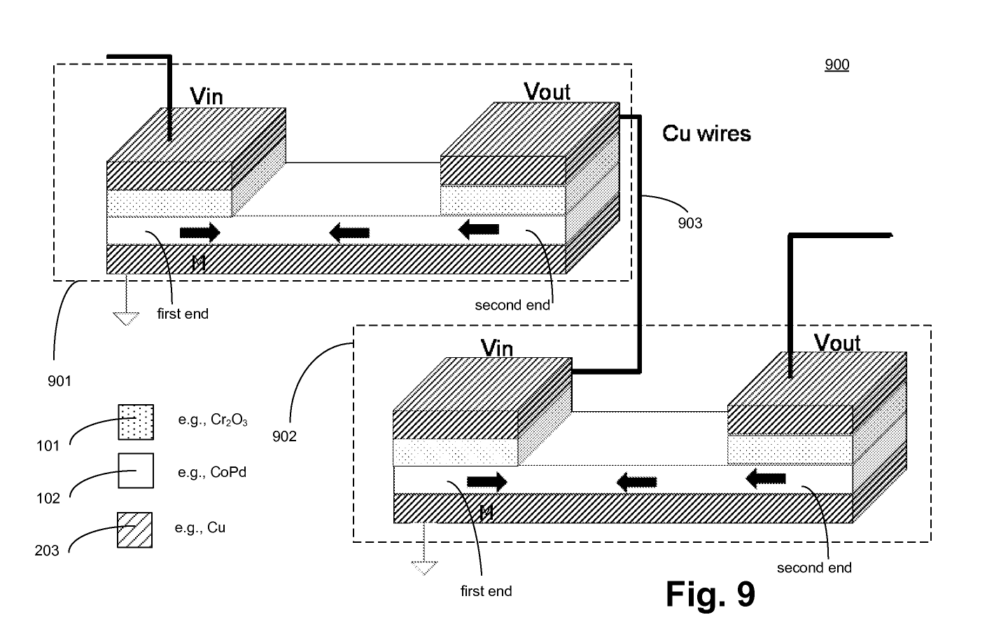

FIG. 9 illustrates hybrid interconnect 900 having two interconnects 901 and 902 with ME devices such that the two interconnects are coupled by a non-magnetic conductor 903, according to some embodiments of the disclosure. It is pointed out that those elements of FIG. 9 having the same reference numbers (or names) as the elements of any other figure can operate or function in any manner similar to that described, but are not limited to such.

The term “hybrid” interconnect here generally refers to magnetic and electric interconnects combined together. In this example, interconnects 901 and 902 are magnetic interconnects having ME devices on either ends of FM layer 102. In some embodiments, when a voltage is applied to the first terminal Vin (which is at the first end of interconnect 901) an effective magnetoelectric field (B_{ME}) is formed by an exchange bias at the interface of ME layer 101 and FM layer 102 of interconnect 900. The DW propagates from the first end of interconnect 901 to second end of interconnect 901. The ME device on the second end of interconnect 901 behaves as an output ME cell. The magnetization that “propagates” as a DW from the first end to the second end affects the antiferromagnetic order in the output ME cell and thus induces voltage (i.e., output voltage) on terminal Vout of interconnect 901 corresponding to the applied input voltage on terminal Vin.

In some embodiments, a non-magnetic conductive wire (e.g., Cu wire) 903 is coupled to Vout of interconnect 901 and Vin of interconnect 902. The induced voltage on terminal Vout of interconnect 901 is also induced on conductive wire 903 and eventually induces voltage on input terminal Vin of second interconnect 902. In some embodiments, ME cells in interconnects 901 and 902 behave as repeaters while the conductive electric interconnect 903 behaves as link between the repeaters. In some embodiments, the voltage induced on the input terminal Vin of interconnect 902 then causes a DW to propagate from a first end of that interconnect to the other end of interconnect 902 as described with reference to interconnect 901.

In some embodiments, majority gates can also be cascaded using non-magnetic conductive wire. For example, majority gate of FIGS. 7-8 can be cascaded to other interconnects or other majority gates. Using the example of FIG. 8, in some embodiments, interconnect 903 is coupled to the Out terminal at one end and to one or more inputs of another majority gate.

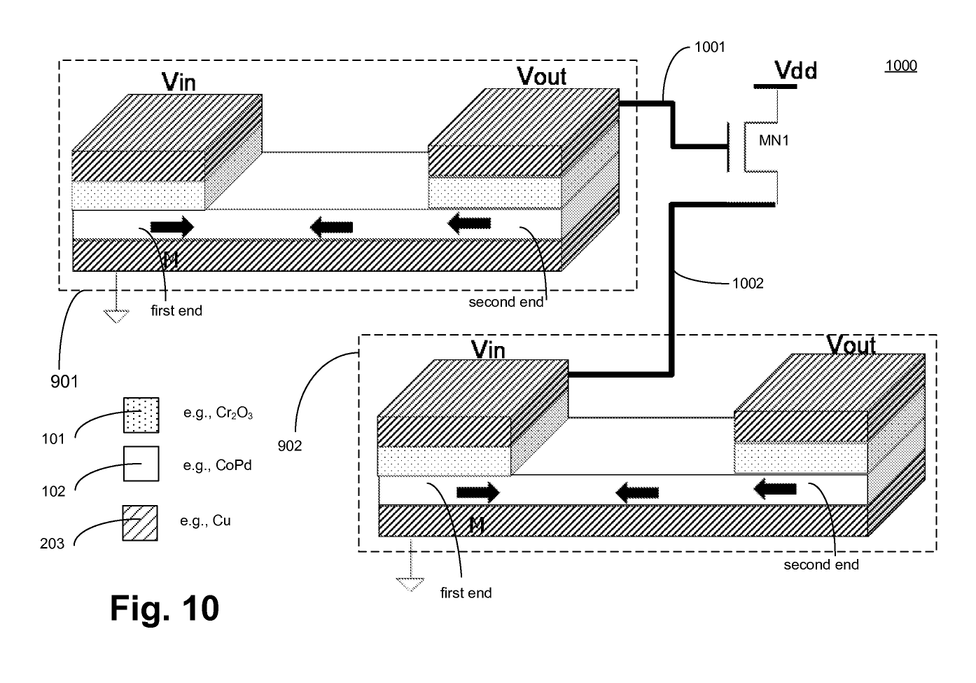

FIG. 10 illustrates hybrid interconnect 1000 having two interconnects 901 and 902 with ME devices such that the two interconnects are coupled by a non-magnetic conductor 1001/1002 and a transistor, according to some embodiments of the disclosure. It is pointed out that those elements of FIG. 10 having the same reference numbers (or names) as the elements of any other figure can operate or function in any manner similar to that described, but are not limited to such. FIG. 10 is described with reference FIG. 9 and differences between FIG. 10 and FIG. 9 are described.

In some embodiments, terminal Vout of interconnect 901 is coupled to a gate terminal of a transistor via an electric interconnect 1001 (e.g., Cu interconnect). In this example, an n-type transistor MN1 is shown. However, the embodiments can be implemented with any number and types of transistors (including p-type). Here, the source terminal of MN1 is coupled to another electrical interconnect 1002 (e.g., Cu interconnect) and the drain terminal of MN1 is coupled to a supply terminal (e.g., Vdd). In some embodiments, interconnect 1002 is coupled to input terminal Vin of the second interconnect 902.

While the embodiment of FIG. 10 is illustrated with reference to interconnects of FIGS. 7A-B and/or FIG. 8, the concept is applicable to other types of interconnects. For example, in some embodiments, interconnect of FIG. 4 (which includes ME device 401 and tunnel junction device 402 on either ends of FM layer 102, respectively, can also be cascaded with other interconnects using a non-magnetic conductive wires and one or more intervening transistors. In some embodiments, interconnect 903 is coupled to terminal V2 of FIG. 4 at one end and a gate terminal of a transistor at another end. In some embodiments, the source/drain terminal of the transistor is coupled to terminal V1 of another interconnect (like that of FIG. 4 or any other magnetic interconnect). In some embodiments, the transistor drives current through terminal V2 and the MTJ stack of 901 to create the voltage that the transistor driving 903 is sensing.

In some embodiments, majority gates can also be cascaded using non-magnetic conductive wire(s). For example, majority gate of FIGS. 7-8 can be cascaded to other interconnects and/or transistors or other majority gates. Using the example of FIG. 8, in some embodiments, interconnect 903 is coupled to the Out terminal at one end and gate terminal of a transistor at another end. In some embodiments, the source/drain terminal of the transistor is coupled to one or more inputs of another majority gate.

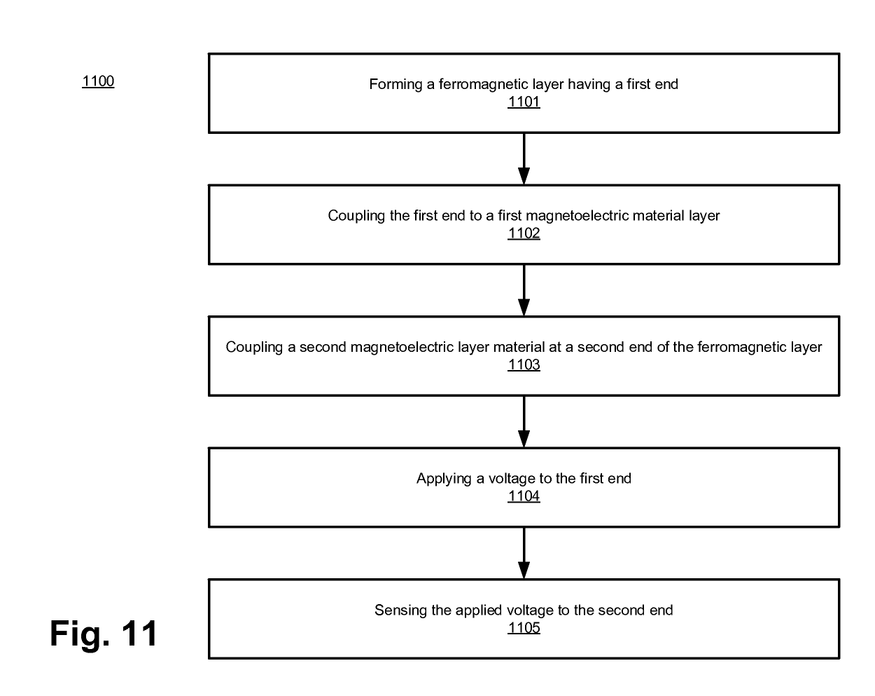

FIG. 11 illustrates flowchart 1100 of a method for forming and using an interconnect having magnetoelectric devices, according to some embodiments of the disclosure. It is pointed out that those elements of FIG. 11 having the same reference numbers (or names) as the elements of any other figure can operate or function in any manner similar to that described, but are not limited to such.

Although the blocks in the flowchart with reference to FIG. 11 are shown in a particular order, the order of the actions can be modified. Thus, the illustrated embodiments can be performed in a different order, and some actions/blocks may be performed in parallel. Some of the blocks and/or operations listed in FIG. 11 are optional in accordance with certain embodiments. The numbering of the blocks presented is for the sake of clarity and is not intended to prescribe an order of operations in which the various blocks must occur. Additionally, operations from the various flows may be utilized in a variety of combinations.

At block 1101, FM layer 102 is formed having two ends—a first end and a second end. First ME layer 101 is then deposited on FM layer 102. At block 1102, the first end of FM layer 102 is coupled to the first ME layer 101. At block 1103, a second ME layer 101 is deposited on FM layer 102 and coupled to the second end of FM layer 102. In some embodiments, the gap between the first and second ME layers 101 at either ends of the FM interconnect is filled with a dielectric (e.g., SiO₂). In some embodiments, non-magnetic conductive layers (e.g., Cu) are deposited on the ME layer 101 to form first and second terminals respectively. In some embodiments, non-magnetic conductive layer (e.g., Cu) is deposited on FM layer 102 to form third terminal V3. The resulting structure formed is similar to the one formed in FIG. 5A. A similar process can be used for forming any of the various interconnects and majority gates described in this disclosure.

Referring back to FIG. 11, at block 1104, a voltage is applied to the first end (i.e., V1 or Vin). The voltage induced on the input terminal Vin of interconnect then causes a changed magnetization state and DW to propagate from the first end of that interconnect to the other end of interconnect. At block 1105, a voltage is sensed on the output voltage terminal Vout (or V2) of the FM interconnect which is the voltage inducted by the DW propagation. The magnetization that “propagates” as the magnetization propagated with the DW from the first end to the second end affects the antiferromagnetic order in the output ME cell and thus induces voltage (i.e., output voltage) on the terminal Vout of the interconnect corresponding to the applied input voltage on terminal Vin.

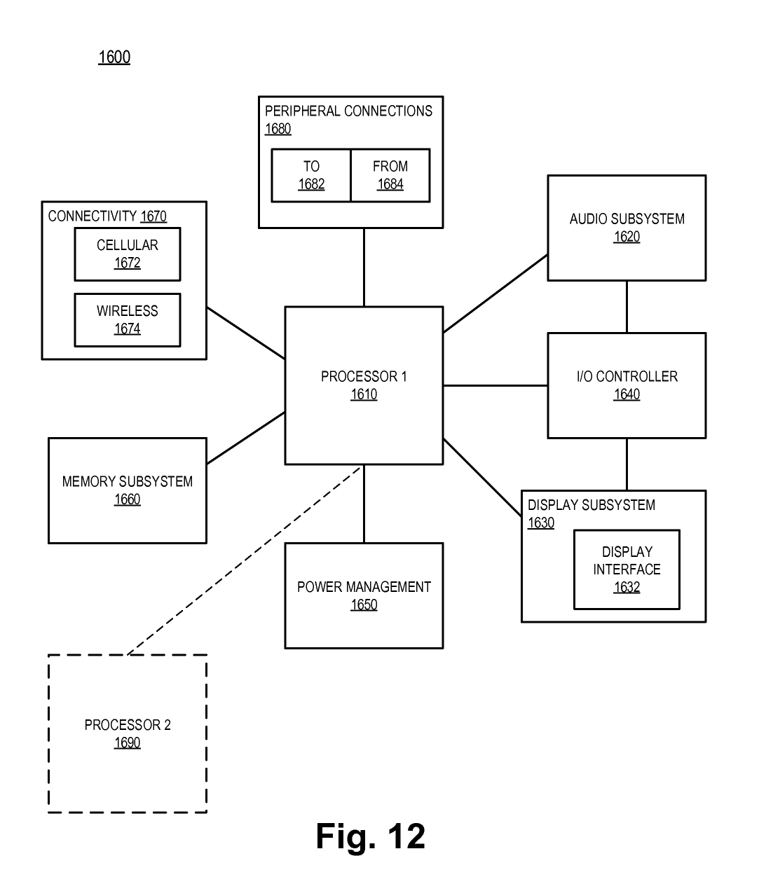

FIG. 12 illustrates a smart device 1600 or a computer system or a SoC (System-on-Chip) with an interconnect having ME devices, memory cell(s), and/or a majority gate(s), according to some embodiments. It is pointed out that those elements of FIG. 12 having the same reference numbers (or names) as the elements of any other figure can operate or function in any manner similar to that described, but are not limited to such.

FIG. 12 illustrates a block diagram of an embodiment of a mobile device in which flat surface interface connectors could be used. In some embodiments, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600.

In some embodiments, computing device 1600 includes a first processor 1610 with an interconnect having ME devices, a memory cell, and/or a majority gate, according to some embodiments discussed. Other blocks of the computing device 1600 may also include an interconnect having ME devices, a memory cell, and/or a majority gate of some embodiments. The various embodiments of the present disclosure may also comprise a network interface within 1670 such as a wireless interface so that a system embodiment may be incorporated into a wireless device, for example, cell phone or personal digital assistant.

In some embodiments, processor 1610 (and/or processor 1690) can include one or more physical devices, such as microprocessors, application processors, microcontrollers, programmable logic devices, or other processing means. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In some embodiments, computing device 1600 includes audio subsystem 1620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

In some embodiments, computing device 1600 includes display subsystem 1630. Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

In some embodiments, computing device 1600 includes I/O controller 1640. I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In some embodiments, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In some embodiments, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600.

Elements of embodiments are also provided as a machine-readable medium (e.g., memory 1660) for storing the computer-executable instructions (e.g., instructions to implement any other processes discussed herein). The machine-readable medium (e.g., memory 1660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, computing device 1600 comprises connectivity 1670. Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

In some embodiments, computing device 1600 includes Peripheral connections 1680. Peripheral connections 1680 include hardware interfaces and connectors, as well as software components (e.g., drivers, protocol stacks) to make peripheral connections. It will be understood that the computing device 1600 could both be a peripheral device (“to” 1682) to other computing devices, as well as have peripheral devices (“from” 1684) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, an interconnect is provided which comprises: a first end having a ferromagnetic layer coupled to a first magnetoelectric material layer; and a second end having a second magnetoelectric material layer coupled to the ferromagnetic layer, wherein the ferromagnetic layer extends from the first end to the second end. In some embodiments, the first end is coupled to a driver providing an input voltage to the first magnetoelectric material layer.

In some embodiments, the first magnetoelectric material layer is a single layer. In some embodiments, the first magnetoelectric material layer is a hybrid magnetoelectric material layer. In some embodiments, the hybrid magnetoelectric material layer comprises a piezoelectric material which exerts magnetostriction on the ferromagnetic layer. In some embodiments, the second end is coupled to a receiver to detect an output voltage associated with the second magnetoelectric material layer.

In some embodiments, the first and second magnetoelectric material layers are composed of one of: BiFeO₃, BiMnFe₃, NiCl, Ni₃B₇O₁₃Cl, or Cr₂O₃. In some embodiments, the ferromagnetic layer is a layer formed from one or more of: CoFeB; Co, Fe, Ni, or Gd alloys; or Huseler alloys. In some embodiments, when a voltage is applied to the first end on the first magnetoelectric material layer, a domain wall traverses through the ferromagnetic layer. In some embodiments, the first or second ends are coupled to one end of a conductive wire such that a second end of the conductive wire is coupled to another interconnect which includes: a first end having a ferromagnetic layer coupled to a first magnetoelectric material layer; and a second end having a second magnetoelectric material layer coupled to the ferromagnetic layer, wherein the ferromagnetic layer extends from the first end to the second end of the other interconnect.

In some embodiments, the first or second ends are coupled to one end of a conductive wire such that a second end of the conductive wire is coupled a switching device. In some embodiments, the switching device is a transistor, and wherein the second end of the conductive wire is coupled to a gate terminal of the switching device. In some embodiments, a source terminal of the switching device is coupled to another conductive wire which is coupled another interconnect, wherein the other interconnect comprises: a first end having a ferromagnetic layer coupled to a first magnetoelectric material layer; and a second end having a second magnetoelectric material layer coupled to the ferromagnetic layer, wherein the ferromagnetic layer extends from the first end to the second end of the other interconnect.

In another example, a magnetic logic gate device comprising: a ferromagnetic layer; and first, second, third, and fourth magnetoelectric material layers coupled to the ferromagnetic layer. In some embodiments, the ferromagnetic layer is configured in a shape of a ring. In some embodiments, the first, second, third, and fourth magnetoelectric material layers are composed of one of: BiFeO₃, BiMnFe₃, NiCl, Ni₃B₇O₁₃Cl, or Cr₂O₃. In some embodiments, the ferromagnetic layer is a layer formed from one of CoFeB; Co, Fe, Ni, or Gd alloys; or Huseler alloys. In some embodiments, the first, second, third, and fourth magnetoelectric material layers are coupled to respective linear portions of the ferromagnetic layer, wherein the respective linear portions are then coupled to the ring formed from the ferromagnetic layer.

In some embodiments, the first, second, and fourth magnetoelectric material layers are coupled to drivers to provide respective voltage potentials on the first, second, and fourth multi-magnetic layers. In some embodiments, the third magnetoelectric material layer is coupled to a receiver to detect voltage potential on the third multi-magnetic layer.

In some embodiments, the third magnetoelectric material layer is coupled to one end of a conductive wire such that a second end of the conductive wire is coupled to another interconnect which includes: a first end having a ferromagnetic layer coupled to a first magnetoelectric material layer; and a second end having a second magnetoelectric material layer coupled to the ferromagnetic layer, wherein the ferromagnetic layer extends from the first end to the second end of the other interconnect.

In some embodiments, the third magnetoelectric material layer is coupled to one end of a conductive wire such that a second end of the conductive wire is coupled a switching device. In some embodiments, the switching device is a transistor, and wherein the second end of the conductive wire is coupled to a gate terminal of the switching device. In some embodiments, a source terminal of the switching device is coupled to another conductive wire which is coupled another interconnect, wherein the other interconnect comprises: a first end having a ferromagnetic layer coupled to a first magnetoelectric material layer; and a second end having a second magnetoelectric material layer coupled to the ferromagnetic layer, wherein the ferromagnetic layer extends from the first end to the second end of the other interconnect.

In another example, an apparatus is provided which comprises: a first end having a ferromagnetic layer coupled to a first magnetoelectric material layer; and a second end having a tunnel junction device coupled to the ferromagnetic layer, wherein the ferromagnetic layer extends from the first end to the second end. In some embodiments, the first end is coupled to a driver providing an input voltage to the first magnetoelectric material layer. In some embodiments, the first magnetoelectric material layer is a single layer. In some embodiments, the first magnetoelectric material layer is a hybrid magnetoelectric material layer. In some embodiments, the hybrid magnetoelectric material layer comprises a piezoelectric material which exerts magnetostriction on the ferromagnetic layer. In some embodiments, the tunnel junction device is coupled to a receiver to detect an output.

In another example, a system is provided which comprises: a memory; a processor coupled to the memory, the processor having an apparatus according to the apparatus described above; and a wireless interface for allowing the processor to couple to another device.

In another example, an apparatus is provided which comprises: a first terminal coupled to a tunneling junction device; a second terminal coupled to a layer coupling the tunneling junction device and a magnetoelectric device; and a third terminal coupled to the magnetoelectric device. In some embodiments, a voltage source coupled to the second and third terminal, wherein the voltage source is operable to switch magnetization in the layer coupling the tunneling junction device and the magnetoelectric device. In some embodiments, the apparatus comprises a sensor to sense a difference between voltages on the first and second terminals to sense magnetization in the layer coupling the tunneling junction device and the magnetoelectric device.

In another example, a system is provided which comprises: a memory; a processor coupled to the memory, the processor having an apparatus according to the apparatus described above; and a wireless interface for allowing the processor to couple to another device.

In another example, a system is provided which comprises: a memory; a processor coupled to the memory, the processor having an interconnect according to the interconnect described above; and a wireless interface for allowing the processor to couple to another device.

In another example, a system is provided which comprises: a memory; a processor coupled to the memory, the processor having a magnetic logic gate device according to the magnetic logic described above; and a wireless interface for allowing the processor to couple to another device.

In another example, a method is provided which comprises: forming a ferromagnetic layer coupled to a first magnetoelectric material layer, the ferromagnetic layer having a first end and second end; and forming a second magnetoelectric material layer coupled to the ferromagnetic layer at the second end, wherein the ferromagnetic layer extends from the first end to the second end. In some embodiments, the method comprises: coupling the first end to a driver which is to provide an input voltage to the first magnetoelectric material layer.

In some embodiments, the first magnetoelectric material layer is a single layer. In some embodiments, the first magnetoelectric material layer is a hybrid magnetoelectric material layer. In some embodiments, the hybrid magnetoelectric material layer comprises a piezoelectric material which exerts magnetostriction on the ferromagnetic layer. In some embodiments, the method comprises: coupling the second end to a receiver to detect an output voltage associated with the second magnetoelectric material layer. In some embodiments, the first and second magnetoelectric material layers are composed of one of: BiFeO₃, BiMnFe₃, NiCl, Ni₃B₇O₁₃Cl, or Cr₂O₃.

In some embodiments, the ferromagnetic layer is a layer formed from one or more of: CoFeB; Co, Fe, Ni, or Gd alloys; or Huseler alloys. In some embodiments, the method comprises: applying a voltage to the first end on the first magnetoelectric material layer. In some embodiments, the method comprises: coupling the first or second ends to one end of a conductive wire; coupling a second end of the conductive wire to another interconnect which includes: a first end having a ferromagnetic layer coupled to a first magnetoelectric material layer; and a second end having a second magnetoelectric material layer coupled to the ferromagnetic layer, wherein the ferromagnetic layer extends from the first end to the second end of the other interconnect.

In some embodiments, the method comprises: coupling the first or second ends to one end of a conductive wire; and coupling a second end of the conductive wire to a switching device. In some embodiments, the switching device is a transistor, and wherein the method comprises coupling the second end of the conductive wire to a gate terminal of the switching device. In some embodiments, the method comprises: coupling a source terminal of the switching device to another conductive wire which is coupled another interconnect, wherein the other interconnect comprises: a first end having a ferromagnetic layer coupled to a first magnetoelectric material layer; and a second end having a second magnetoelectric material layer coupled to the ferromagnetic layer, wherein the ferromagnetic layer extends from the first end to the second end of the other interconnect.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-26. canceled

27. An interconnect comprising:
a first end having a ferromagnetic layer coupled to a first magnetoelectric material layer; and
a second end having a second magnetoelectric material layer coupled to the ferromagnetic layer, wherein the ferromagnetic layer extends from the first end to the second end.

28. The interconnect of claim 27, wherein the first end is coupled to a driver providing an input voltage to the first magnetoelectric material layer.

29. The interconnect of claim 27, wherein the first magnetoelectric material layer is a single layer.

30. The interconnect of claim 27, wherein the first magnetoelectric material layer is a hybrid magnetoelectric material layer.

31. The interconnect of claim 30, wherein the hybrid magnetoelectric material layer comprises a piezoelectric material which exerts magnetostriction on the ferromagnetic layer.

32. The interconnect of claim 27, wherein the second end is coupled to a receiver to detect an output voltage associated with the second magnetoelectric material layer.

33. The interconnect of claim 27, wherein the first and second magnetoelectric material layers include one of:
BiFeO₃,
BiMnFe₃,
NiCl,
Ni₃B₇O₁₃Cl, or
Cr₂O₃.

34. The interconnect of claim 27, wherein the ferromagnetic layer is a layer includes one or more of:
CoFeB;
Co, Fe, Ni, or Gd alloys; or
Huseler alloys.

35. The interconnect of claim 27, wherein when a voltage is applied to the first end on the first magnetoelectric material layer, a domain wall traverses through the ferromagnetic layer.

36. The interconnect of claim 27, wherein the first or second ends are coupled to one end of a conductive wire such that a second end of the conductive wire is coupled to another interconnect which includes:
a first end having a ferromagnetic layer coupled to a first magnetoelectric material layer; and
a second end having a second magnetoelectric material layer coupled to the ferromagnetic layer, wherein the ferromagnetic layer extends from the first end to the second end of the other interconnect.

37. The interconnect of claim 27, wherein the first or second ends are coupled to one end of a conductive wire such that a second end of the conductive wire is coupled a switching device.

38. The interconnect of claim 37, wherein the switching device is a transistor, and wherein the second end of the conductive wire is coupled to a gate terminal of the switching device.

39. The interconnect of claim 38, wherein a source terminal of the switching device is coupled to another conductive wire which is coupled another interconnect, wherein the other interconnect comprises:
a first end having a ferromagnetic layer coupled to a first magnetoelectric material layer; and
a second end having a second magnetoelectric material layer coupled to the ferromagnetic layer, wherein the ferromagnetic layer extends from the first end to the second end of the other interconnect.

40. A magnetic logic gate device comprising:
a ferromagnetic layer; and
first, second, third, and fourth magnetoelectric material layers coupled to the ferromagnetic layer.

41. The magnetic logic gate device of claim 40, wherein the ferromagnetic layer is configured in a shape of a ring.

42. The magnetic logic gate device of claim 40, wherein the first, second, third, and fourth magnetoelectric material layers include one of:
BiFeO₃,
BiMnFe₃,
NiCl,
Ni₃B₇O₁₃Cl, or
Cr₂O₃.

43. The magnetic logic gate device of claim 40, wherein the ferromagnetic layer is a layer which includes one of CoFeB; Co, Fe, Ni, or Gd alloys; or Huseler alloys

44. The magnetic logic gate device of claim 40, wherein the first, second, third, and fourth magnetoelectric material layers are coupled to respective linear portions of the ferromagnetic layer, wherein the respective linear portions are then coupled to the ring formed from the ferromagnetic layer.

45. A system comprising:
a memory;
a processor coupled to the memory, the processor having an interconnect which includes:
a first end having a ferromagnetic layer coupled to a first magnetoelectric material layer; and
a second end having a second magnetoelectric material layer coupled to the ferromagnetic layer, wherein the ferromagnetic layer extends from the first end to the second end; and
a wireless interface for allowing the processor to couple to another device.

46. The interconnect of claim 27, wherein the first and second magnetoelectric material layers include one of:
BiFeO₃,
BiMnFe₃,
NiCl,
Ni₃B₇O₁₃Cl, or
Cr₂O₃.
